(19) United States
(12) Patent Application Publication
(10) Pub. No.: US 2022/0359893 A1
(43) Pub. Date: Nov. 10, 2022

(54) FUEL CELL STACK MODULE FAULT DETECTION SYSTEM AND METHOD

(71) Applicant: Ceres Intellectual Property Company Limited, Horsham West Sussex (GB)

(72) Inventor: Lei Sun, Weifang, Shandong (CN)

(21) Appl. No.: 17/764,636

(22) PCT Filed: Sep. 30, 2020
(86) PCT No.: PCT/IB2020/059163

§ 371 Date: Mar. 29, 2022

(30) Foreign Application Priority Data
Sep. 30, 2019 (CN) 201921663402.4

(51) Int. Cl. H01M 8/04664; H01M 8/04537; G01R 31/12

(52) U.S. Cl. CPC H01M 8/04679; H01M 8/04649; G01R 31/1272; H01M 2250/20

(57) ABSTRACT

A stack module fault detection system, comprising an insulation resistance tester; a stack module, consisting of a plurality of stacks; and a plurality of switch groups, wherein each switch group comprises a first switch and a second switch, each switch group is respectively connected with a stack, the first end of the first switch is connected with the positive electrode of the stack, and the first end of the second switch is connected with the negative electrode of the stack; the second end of the first switch is connected with the positive electrode of the insulation resistance tester, and the second end of the second switch is connected with the negative electrode of the insulation resistance tester. A controller connected with the control end of the switch group controls the opening and closing of the switch group. The insulation resistance tester detects the insulation resistance of each stack in turn and sends the insulation resistance to the controller to monitor the insulation fault in the stack module. Under the condition of not disassembling the stack module, the insulation resistance of each stack is detected, and the stack with insulation fault can be located, so that the operation of fault positioning is simplified.

### TECHNICAL FIELD

The present invention relates to a stack module fault detection system and method.

### BACKGROUND ART

The stack module of a fuel cell is used for supplying power to the fuel cell electric vehicle. The stack module is composed of a plurality of groups of stack strings, and each group of stack strings is composed of a plurality of stacks.

After an insulation fault occurs in the stack module of an existing fuel cell electric vehicle, the stack module is shut down, the stack module disassembled, the insulation resistance of each stack detected one by one, and the stack with the insulation fault determined according to the detected insulation resistance, thus realizing fault location.

Thus, the location of the stack with an insulation fault is complicated.

### SUMMARY OF THE INVENTION

The present invention aims to provide a stack module fault detection system and method for locating the stack with an insulation fault.

A first aspect of the present invention provides a stack module fault detection system, which comprises an insulation resistance tester; a stack module, wherein the stack module is composed of m groups of stack strings in parallel connection, each group of stacks is composed of n stacks in series, m is a positive integer greater than or equal to 1, and n is a positive integer greater than or equal to 1; a plurality of switch groups, wherein each switch group comprises a first switch and a second switch, each switch group is respectively connected with a stack, the first end of the first switch is connected with a positive electrode of the stack, and the first end of the second switch is connected with a negative electrode of the stack; the second end of the first switch is connected with the positive electrode of the insulation resistance tester, and the second end of the second switch is connected with the negative electrode of the insulation resistance tester; controllers respectively connected with the control end of the first switch and the control end of the second switch, wherein the controller controls synchronous opening and closing of the first switch and the second switch connected with the same stack; and the insulation resistance tester sequentially detects the insulation resistance of each stack and sends the detected insulation resistance to the controller connected with the insulation resistance tester to monitor insulation fault in the stack module.

The system can further comprise a stack precharging unit wherein the positive electrode of the DC bus bar of the stack precharging unit is connected with the positive electrode of each group of stack strings; the negative electrode of the DC bus bar of the stack precharging unit is connected with the negative electrode of each group of stack strings.

A first diode and a second diode respectively can be connected to each group of stacks in series. An anode of the first diode is connected with the positive electrode of each group of stack strings, and a cathode of the first diode is connected with the positive electrode of the DC bus of the stack precharging unit; the anode of the second diode is connected with the negative electrode of the DC bus of the stack precharging unit, and the cathode of the second diode is connected with the negative electrode of each group of stack strings.

The system can further comprise m power switches; wherein a control end of each power switch is respectively connected with the controller; opening and closing of the power switch is controlled by the controller; and connection between the positive electrode of the DC bus bar of the stack precharging unit and the positive electrode of each group of stack strings comprises the following steps: the first end of each power switch is connected with the positive electrode of a group of stack strings, and the second end of each power switch is connected with the positive electrode of the DC bus of the stack precharging unit.

The insulation resistance tester can be connected to the controller through a CAN bus, and the tested insulation resistance is sent to the controller connected with the insulation resistance tester to monitor the insulation fault in the stack module, comprising sending the detected insulation resistance to the controller through the CAN bus to pass through the insulation fault in the controller stack module.

The first switch and the second switch can both comprise isolated power electronics.

The system can further comprise a third switch connected between different stacks in each group of stack strings, the control end of the third switch being connected to the controller.

A second aspect of the invention provides a stack module fault detection method for use with a system, comprising an insulation resistance tester; a stack module composed of m groups of stack strings in parallel connection, each group of stack strings being composed of n stacks in series, wherein m and n are positive integer greater than or equal to 1; a plurality of switch groups, wherein each switch group comprises a first switch and a second switch, each switch group is respectively connected with a stack, the first end of the first switch is connected with the positive electrode of the stack and the first end of the second switch is connected with the negative electrode of the stack and the second end of the first switch is connected with the positive electrode of the insulation resistance tester, and the second end of the second switch is connected with the negative electrode of the insulation resistance tester; and controllers respectively connected with the control end of the first switch and the control end of the second switch, wherein the controllers are configured to control synchronous opening and closing of the first switch and the second switch connected with the same stack; wherein the method comprise sequentially detecting the insulation resistance of each stack with the insulation resistance tester and sending the detected insulation resistance to the controller connected with the insulation resistance tester to monitor insulation fault in the stack module.

The present invention provides a stack module fault detection system, which comprises an insulation resistance tester and a stack module. The stack module comprises of a plurality of stacks. Switch groups comprises a first switch and a second switch and each switch group is respectively connected with a stack The first end of the first switch is connected with the positive electrode of the stack, and the first end of the second switch is connected with the negative electrode of the stack. The second end of the first switch is connected with the positive electrode of the insulation resistance tester, and the second end of the second switch is connected with the negative electrode of the insulation resistance tester. Controllers are respectively connected with the control end of the first switch and the control end of the second switch, wherein the controller controls synchronous opening and closing of the first switch and the second switch connected with the same stack The insulation resistance tester sequentially detects the insulation resistance of each stack and sends the detected insulation resistance to the controller connected with the insulation resistance tester to monitor insulation fault in the stack module. It can be seen that in the present invention, through the synchronous opening and closing of the first switch and the second switch connected to each stack, the insulation resistance tester can detect the insulation resistance of each stack one by one, thus realizing the detection of the insulation resistance of each stack without disassembling the stack module, and can locate the stack with insulation fault, thus simplifying the operation of fault positioning.

### BRIEF DESCRIPTION OF THE DRAWINGS

The drawings used in the description of the embodiments will be briefly described below. The drawings in the description below are some embodiments of the present invention.

FIG. 1 is a structural schematic diagram of the stack module fault detection system.

FIG. 2 is another structural schematic diagram of the stack module fault detection system.

### DESCRIPTION OF EMBODIMENTS

Embodiments of the invention will be described in combination with the drawings. The described embodiments are part of the embodiments of the invention, but not all of the embodiments.

The present embodiment provides a stack module fault detection system and method, through which the problem of whether an insulation fault exists in a stack in the stack module can be realized, and the stack where the insulation fault occurs can be quickly and accurately located.

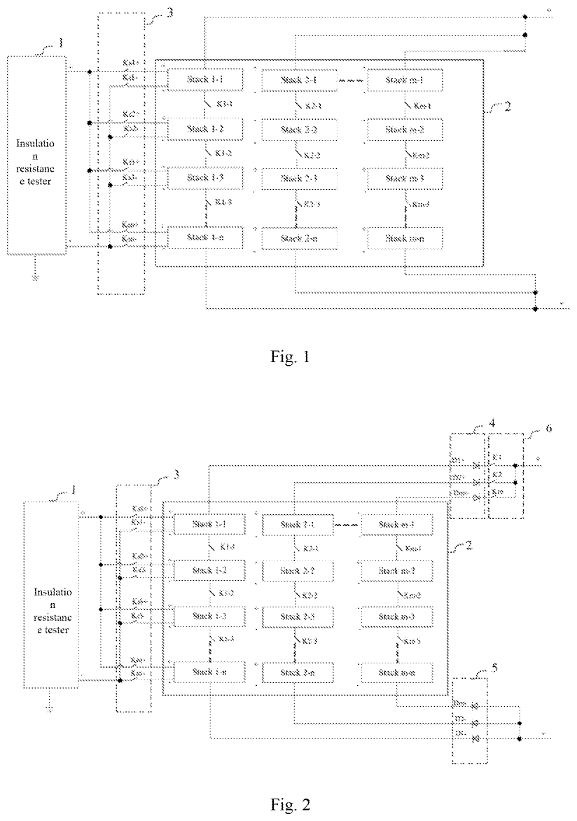

Referring to FIG. 1, the stack module fault detection system in this embodiment comprises an insulation resistance tester 1; a stack module 2, wherein the stack module 2 is composed of m groups of stack strings in parallel connection, each group of stack strings is composed of n stacks in series, m is a positive integer greater than or equal to 1, and n is a positive integer greater than or equal to 1; a plurality of switch groups 3, wherein each switch group comprises a first switch and a second switch, each switch group is respectively connected with a stack, the first end of the first switch is connected with a positive electrode of the stack, and the first end of the second switch is connected with a negative electrode of the stack. The second end of the first switch is connected to the positive electrode of the insulation resistance tester 1, and the second end of the second switch is connected to the negative electrode of the insulation resistance tester 1. Controllers are respectively connected with the control end of the first switch and the control end of the second switch, wherein the controller controls synchronous opening and closing of the first switch and the second switch connected with the same stack.

In FIG. 1, the first group of stack strings consists of n stacks: Stack1-1, Stack1-2, Stack1-3, . . . , Stack1-n, the second group of stack strings consists of n stacks: Stack2-1, Stack2-2, Stack2-3, . . . , Stack2-n, and so on, and the m^{th} group of stack strings consists of n stacks: Stackm-1, Stackm-2, Stackm-3, and Stackm-n.

Taking the first stack Stack1-1 in the first group of stack strings as an example, the stack Stack1-1 is connected to a switch group including a first switch Ks1+ and a second switch Ks1−; the positive electrode of the stack Stack1-1 is connected to the first end of the first switch Ks1+, and the negative electrode of the stack Stack1-1 is connected to the first end of the second switch Ks1−.

The second end of the first switch Ks1+ is connected to the positive electrode of the insulation resistance tester 1, and the second end of the second switch Ks1− is connected to the negative electrode of the insulation resistance tester 1.

The detection system in this embodiment also comprises a controller, not shown in FIG. 1. The controller is respectively connected with the control end of the first switch and the control end of the second switch and can control the opening and closing of the first switch and the second switch. At the same time, the controller is also connected with the insulation resistance tester 1 to receive the insulation resistance of the stack detected by the insulation resistance tester 1.

Optionally, the controller in this embodiment can be an FCU, and the controller and the insulation resistance tester 1 can be connected through a CAN bus to receive the insulation resistance sent by the insulation resistance tester 1 through the CAN bus.

Since each stack is connected with two switches, namely, the first switch connected with the positive electrode of the stack and the second switch connected with the negative electrode of the stack, the controller is connected with the control ends of the two switches connected with each stack, and the opening and closing of the two switches connected with each stack can be controlled through the controller.

In use, the controller controls synchronous opening and closing of the two switches connected to the same stack.

After the controller controls the two switches connected to a stack to be synchronously closed, the positive electrode of the stack is connected with the positive electrode of the insulation resistance tester, and the negative electrode of the stack is connected with the negative electrode of the insulation resistance tester to form a closed loop between the stack and the insulation resistance tester. At this time, the insulation resistance tester can detect the insulation resistance of the stack.

Based on this, the insulation resistance tester can successively detect the insulation resistance of each stack in the stack module. The principle of detecting the insulation resistance by the insulation resistance tester 1 is the same as that of detecting the insulation resistance in the known systems and will not be described here.

After the insulation resistance tester detects the insulation resistance of the stack, the detected insulation resistance is sent to a controller connected with the insulation resistance tester to detect whether each stack in the stack module has insulation fault according to insulation resistance.

Optionally, in this embodiment, both the first switch and the second switch are isolated power electronics, such as MOS tubes, IGBT or silicon carbide tubes. That is, the first switch is one of MOS tube, IGBT or silicon carbide tube, and the second switch is also one of MOS tube, IGBT or silicon carbide tube.

The stack module fault detection system provided by the embodiment comprises an insulation resistance tester; a stack module, wherein the stack module comprises m groups of stack strings in parallel connection, each group of stack strings is composed of n stacks in series, m is a positive integer greater than or equal to 1, and n is a positive integer greater than or equal to 1; wherein the positive electrode of each stack is connected with the first end of the first switch, and the negative electrode of each stack is connected with the first end of the second switch; the second end of the first switch is connected with the positive electrode of the insulation resistance tester, and the second end of the second switch is connected with the negative electrode of the insulation resistance tester. Controllers are respectively connected with the control end of the first switch and the control end of the second switch, wherein the controller controls synchronous opening and closing of the first switch and the second switch connected with the same stack; and the insulation resistance tester sequentially detects the insulation resistance of each stack and sends the detected insulation resistance to the controller connected with the insulation resistance tester to monitor insulation fault in the stack module. It can be seen that in the present invention, through the synchronous opening and closing of the first switch and the second switch connected to each stack, the insulation resistance tester can detect the insulation resistance of each stack one by one, and further, it is not necessary to operate the insulation resistance tester after disassembling the stack module to separately detect the insulation resistance of each stack, thus simplifying the operation of locating the stack with insulation fault.

The stack module is used for providing power for the fuel cell electric vehicle. Specifically, the stack module is connected with the stack precharging unit of the electric vehicle, the stack precharging unit is connected with the DC bus of the electric vehicle, and power is supplied to the electric vehicle through the stack precharging unit.

However, in the process of detecting the insulation fault of the stack module, it is not necessary to disassemble the stack module separately. Therefore, the stack module fault detection system provided by the present invention further comprises a stack precharging unit.

The positive electrode of the DC bus bar of the stack precharging unit is connected with the positive electrode of each group of stack strings; and the negative electrode of the DC bus bar of the stack precharging unit is connected with the negative electrode of each group of stack strings to realize power supply for the fuel cell electric vehicle through the stack precharging unit.

On the basis of including the stack precharging unit, as shown in FIG. 2, the stack module fault detection system of the present embodiment further comprises on the basis of FIG. 1, a first diode 4 and a second diode 5 respectively connected to each group of stacks in series. An anode of the first diode 4 is connected with the positive electrode of each group of stack strings, and the cathode of the first diode 4 is connected with the positive electrode of the DC bus of the stack precharging unit. The anode of the second diode 5 is connected with the negative electrode of the DC bus of the stack precharging unit, and the cathode of the second diode 5 is connected with the negative electrode of each group of stack strings. That is, in this embodiment, the direction of each of the first diodes 4 and each of the second diodes 5 is consistent with the current direction when the stack string supplies power to the stack precharging unit.

Optionally, the first diode 4 and the second diode 5 can be power diodes.

In this embodiment, the first diode 4 is arranged at the positive electrode of each group of stack strings and the second diode 5 is arranged at the negative electrode of each group of stack strings, so that the positive and negative electrodes of different stack strings are mutually isolated, and the problem that different stack strings interfere with each other due to voltage imbalance is avoided.

As shown in FIG. 2, the stack module fault detection system in this embodiment further comprises m power switches 6.

The control end of each power switch is respectively connected with the controller. The opening and closing of the power switch is controlled by the controller. The first end of each power switch is connected with the positive electrode of a group of stack strings, and the second end of each power switch is connected with the positive electrode of the DC bus of the stack precharging unit.

As shown in FIG. 2, the positive electrode of the first group of stack strings, namely, the positive electrode of the Stack1-1 stack, is connected to the first diode D1+, and the negative electrode of the first group of stack strings, namely, the negative electrode of the Stack1-n stack, is connected to the second diode D1−.

The positive electrode of the first group of stack strings, namely, the positive electrode of the Stack1-1 stack, is connected to the first end of the first power switch K1, and the second end of the first power switch K1 is connected to the positive electrode of the DC bus of the stack precharging unit.

Similarly, the positive electrode of the i^{th} group of stack strings, namely, the positive electrode of the Stacki-1 stack, is connected to the first diode Di+, and the negative electrode of the i^{th} group of stack strings, namely, the negative electrode of the Stacki-n stack, is connected to the second diode Di−.

The positive electrode of the i^{th} group of stack strings, namely, the positive electrode of the Stacki-1 stack, is connected to the first end of the i^{th} group of power switch Ki, and the second end of the i^{th} power switch Ki is connected to the positive electrode of the DC bus of the stack precharging unit.

In this embodiment, a power switch is arranged at the DC bus output interface of each group of stack strings to control each group of stack strings to close or open the connection with the main DC bus respectively. When the insulation fault of the stacks in a certain group of stack strings is detected, the controller controls the corresponding connected power switches of the group of stack strings to be disconnected, cuts off the connection between the stacks with insulation fault and the DC bus, prevents the faulty stack strings from further insulation fault, and ensures the whole vehicle to work in the extended range mode under the operation of other normal stack strings.

Optionally, in other embodiments, the stack module fault detection system may further include a third switch connected between different stacks in each group of stack strings, wherein the control end of the third switch is connected to the controller. The third switch can be a power electronics.

Different stacks in each group of stack strings are connected by power electronics, and the controller can control the opening and closing of power electronics connected between different stacks.

When the insulation resistance tester detects the insulation resistance of a certain stack, the controller can control the power electronics connected between the stack and other stacks to be disconnected, and disconnect the stack from other adjacent stacks, thus improving the accuracy of the insulation resistance detection results.

The stack module fault detection system provided by the embodiment can detect the insulation resistance of each stack one by one through the insulation resistance tester without disassembling the stack module, which simplifies the operation of positioning the stack with insulation fault, and can realize fast and accurate positioning of the stack with insulation fault. In addition, when it is determined that the insulation resistance of the stack in a certain group of stack strings fails, the controller controls the faulty stack strings to disconnect from the DC bus, thus ensuring the operation of other normal stack strings and effectively improving the safety performance and reliability of the vehicle system powered by the stack module.

Based on the stack module fault detection system shown in FIG. 2, the working principle of stack module fault detection is introduced by taking the detection of insulation resistance of the first group of stack strings as an example. It should be noted that FIG. 2 shows only the connection relationship between the insulation resistance tester and the first group of stack strings. However, the connection relationship between the insulation resistance tester and other groups of stack strings is not shown, and the connection relationship between any group of stack strings and the insulation resistance tester is the same as the connection relationship between the first group of stack strings and the insulation resistance tester shown in FIG. 2.

(1) During operation, the controller such as FCU controls m power switches K1, K2 . . . Km to disconnect the stack module from the DC bus of the electric vehicle.

(2) The FCU controls the two switches Ks1+ and Ks1− in the first switch group to be synchronously closed, controls Ksi+ and Ksi− (n≥i≥2) in other m−1 electronic switch groups except the first switch group to be synchronously disconnected, and controls the third switch K1-1 connected between the Stack1-1 stack and the Stack1-2 stack to be disconnected. The insulation resistance tester detects the insulation resistance of the Stack1-1 stack and sends the detected insulation resistance of the Stack1-1 stack to FCU through the CAN bus.

The FCU controls the two switches Ks2+ and Ks2− in the second switch group to be synchronously closed, controls the synchronous disconnection of Ks1+ and Ks1−, controls the synchronous disconnection of Ksi+ and Ksi−(n≥i≥3), and controls the disconnection of the third switch K1-1 connected between the Stack1-1 stack and the Stack1-2 stack and the disconnection of the third switch K1-3 connected between the Stack1-2 stack and the Stack1-3 stack. The insulation resistance tester detects the insulation resistance of the Stack1-2 stack, and sends the detected insulation resistance of the Stack1-2 stack to FCU through the CAN bus. The insulation resistance of each stack in the first group of stack strings is detected one by one.

(3) The FCU determines whether there are stacks with insulation fault in the first group of stack strings according to the received insulation resistance of each of the stacks in the first group of stack strings.

Through the above steps, the insulation resistance of each stack in the m groups of stack strings is detected respectively, and the detection of whether there is insulation fault in the stack module is realized. In addition, when determining the stacks with insulation faults in a certain group of stacks, the stack strings and stacks with insulation faults can be quickly and accurately located, so that the purpose of locating the fault can be realized without disassembling the stack module.

An insulation resistance tester can be used in the stack module fault detection system of the present invention to respectively realize the detection of the insulation resistance of each stack in m groups of stack strings. It may also include m insulation resistance testers. One insulation resistance tester only detects the insulation resistance of each resistor in a group of stack strings connected to the insulation resistance tester.

The embodiments in the description are all described in a progressive manner and the same or similar parts among the embodiments can be mutually referred to, and each embodiment focuses on the differences from other embodiments.

The above is only a preferred embodiment of the present invention, and various improvements and modifications can be made without departing from the principles of the invention and within the scope of protection of the invention.

1. A stack module fault detection system, comprising:
an insulation resistance tester;
a stack module composed of m groups of stack strings in parallel connection, each group of stack strings being composed of n stacks in series, wherein m and n are positive integer greater than or equal to 1;
a plurality of switch groups, wherein
each switch group comprises a first switch and a second switch,
each switch group is respectively connected with a stack,
the first end of the first switch is connected with the positive electrode of the stack and the first end of the second switch is connected with the negative electrode of the stack and
the second end of the first switch is connected with the positive electrode of the insulation resistance tester, and the second end of the second switch is connected with the negative electrode of the insulation resistance tester; and
controllers respectively connected with the control end of the first switch and the control end of the second switch, wherein the controllers are configured to control synchronous opening and closing of the first switch and the second switch connected with the same stack;
wherein
the insulation resistance tester is configured to sequentially detect the insulation resistance of each stack and send the detected insulation resistance to the controller connected with the insulation resistance tester to monitor insulation fault in the stack module.

2. The detection system according to claim 1, further comprising a stack precharging unit, wherein a positive electrode of a DC bus bar of the stack precharging unit is connected with the positive electrode of each group of stack strings, and a negative electrode of the DC bus bar is connected with a negative electrode of each group of stack strings.

3. The detection system according to claim 2, further comprising:
a first diode and a second diode respectively connected to each group of stack strings in series, wherein an anode of the first diode is connected with a positive electrode of each group of stack strings, a cathode of the first diode is connected with the positive electrode of the DC bus of the stack precharging unit, an anode of the second diode is connected with the negative electrode of the DC bus of the stack precharging unit, and a cathode of the second diode is connected with the negative electrode of each group of stack strings.

4. The detection system according to claim 2, further comprising m power switches, wherein a control end of each power switch is respectively connected with the controller, and opening and closing of the power switch is controllable by the controller;
wherein the connection between the positive electrode of the DC bus bar of the stack precharging unit and the positive electrode of each group of stack strings comprises:
the first end of each power switch is connected with the positive electrode of a group of stack strings, and the second end of each power switch is connected with the positive electrode of the DC bus of the stack precharging unit.

5. The detection system according to claim 1, wherein the insulation resistance tester is connected to the controller through a CAN bus, and is configured to send the tested insulation resistance to the controller connected with the insulation resistance tester to monitor an insulation fault in the stack module by way of sending the detected insulation resistance to the controller through the CAN bus to pass through the insulation fault in the stack module of the controller.

6. The detection system according to claim 1, wherein the first switch and the second switch are isolated power electronics.

7. The detection system according to claim 1, further comprising a third switch connected between different stacks in each group of stack strings, a control end of the third switch being connected to the controller.

8. A stack module fault detection method for use with a system, comprising:
an insulation resistance tester;
a stack module composed of m groups of stack strings in parallel connection, each group of stack strings being composed of n stacks in series, wherein m and n are positive integer greater than or equal to 1;
a plurality of switch groups, wherein
each switch group comprises a first switch and a second switch,
each switch group is respectively connected with a stack,
the first end of the first switch is connected with the positive electrode of the stack and the first end of the second switch is connected with the negative electrode of the stack and
the second end of the first switch is connected with the positive electrode of the insulation resistance tester, and the second end of the second switch is connected with the negative electrode of the insulation resistance tester; and
controllers respectively connected with the control end of the first switch and the control end of the second switch, wherein the controllers are configured to control synchronous opening and closing of the first switch and the second switch connected with the same stack;
wherein the method comprises:
sequentially detecting the insulation resistance of each stack with the insulation resistance tester and sending the detected insulation resistance to the controller connected with the insulation resistance tester to monitor insulation fault in the stack module.
